(19) United States
(12) Patent Application Publication
(10) Pub. No.: US 2026/0238220 A1
(43) Pub. Date: Aug. 13, 2026

(54) DATA CONVERTER BASED ON SEMICONDUCTOR DEVICES

(71) Applicant: Seoul National University R&DB FOUNDATION, Seoul (KR)

(72) Inventors: Jong-Ho LEE, Seoul (KR); Jonghyun KO, Seoul (KR); Jiseong IM, Seoul (KR)

(21) Appl. No.: 19/529,087

(22) Filed: Feb. 3, 2026

Related U.S. Application Data
(60) Provisional application No. 63/755,373, filed on Feb. 7, 2025.

(51) Int. Cl. H03M 1/34; H03M 7/16

(52) U.S. Cl. CPC H03M 1/34; H03M 7/165

(57) ABSTRACT

Provided is a data converter. The data converter includes N bit processing units configured to respectively correspond one-to-one to N bits constituting a digital code and configured to receive an input signal and a reference signal to generate and output a code of a corresponding bit. Each of the bit processing units includes: a signal generation module including a first semiconductor device having a first threshold voltage set according to a position of the corresponding bit in the digital code and configured to receive the input signal; a comparison module including a second semiconductor device having a second threshold voltage and configured to receive the reference signal; a latch module configured to regenerate a potential of an internal node according to operation results of the first semiconductor device and the second semiconductor device based on the input signal and the first threshold voltage and the reference signal and the second threshold voltage; and a signal conversion module configured to convert an output voltage of the latch module into a binary signal and output the binary signal.

### TECHNICAL FIELD

The present invention relates to a data converter, and more particularly, to a data converter based on semiconductor devices configured by arranging semiconductor devices having different threshold voltages in a pipeline form, so that the data converter can be implemented in a small area, can operate with low power, and can be used in various applications including a neuromorphic system to improve performance.

### BACKGROUND ART

An Analog-to-Digital Converter ADC is an electronic device that converts an analog signal into a digital signal. Signals such as temperature and voltage sensed by sensors in nature are analog signals. An ADC circuit converts the above-described analog signals into digital signals that can be processed by electronic devices such as a computer and a control device and outputs the digital signals. Recently, as advanced electronic devices such as IoT and neuromorphic systems have been widely commercialized, the demand for ADCs having low-power and small-area characteristics has further increased. According to such demands, ADCs having various structures have been developed.

U.S. Patent Application Publication No. 2009-0091483 discloses a Flash ADC structure as one of the ADC types. FIG. 1 is a structural diagram illustrating the Flash ADC scheme. As illustrated in FIG. 1, the flash ADC performs an ADC operation that converts an analog signal into a digital signal by using a comparator bank composed of 2^{K} comparators. The comparators of the flash ADC receive a reference voltage corresponding to a reference value and an analog voltage to be determined. The comparators of the flash ADC compare magnitudes of the two input voltages and output a result as a digital code. The flash ADC having such a structure continues to be widely used in applications requiring high speed and low latency.

However, the conventional flash ADC having the above-described structure uses a large number of comparators, and thus a large amount of power consumption occurs during operation. Therefore, the conventional flash ADC is difficult to use in low-power applications. In addition, since the conventional flash ADC uses a large number of comparators, a large chip area is required. Accordingly, the ADC having the above-described structure is difficult to use in compact applications.

In addition, the resolution of the conventional flash ADC is limited according to the number of comparators used. Therefore, in order to increase the resolution of the flash ADC, the number of comparators needs to be increased, and accordingly there is a problem in that the circuit structure of the ADC becomes complicated and the manufacturing cost increases as well as the power consumption increases.

As described above, when the number of bits increases in the ADC having the above-described structure, the device area and power consumption increase exponentially, and it is difficult to use the ADC in applications requiring high resolution.

U.S. Pat. No. 7,965,218 discloses a Successive Approximation Register SAR ADC structure. FIG. 2 is a structural diagram illustrating the SAR ADC scheme according to the related art. As illustrated in FIG. 2, the SAR ADC performs an ADC operation by using one comparator, a DAC, a logic circuit, and a register. In general, bits are sequentially determined starting from a Most Significant Bit MSB. The SAR ADC uses one comparator, and the DAC uses a plurality of capacitors having different sizes and controls an output value of the DAC using a charge sharing principle. A result of the bit determination up to a current time is stored in the register, and according to the result, the DAC adjusts a reference voltage of the comparator through the logic circuit. By repeating the above-described process, bit values are determined from the MSB to a Least Significant Bit LSB.

The SAR ADC having the above-described structure provides high resolution, but still has a problem in that a large circuit area and a large amount of power consumption are required.

### SUMMARY OF THE INVENTION

In order to solve the above-described problems, an object of the present invention is to provide a data converter configured to convert an analog signal into a digital code by using semiconductor devices capable of varying a threshold voltage or conductance and a latch circuit module.

Another object of the present invention is to provide a data converter configured to convert an analog signal into a digital code by using steep switching devices capable of varying a threshold voltage or conductance.

In order to achieve the above technical object, a data converter according to a first aspect of the present invention is an analog-to-digital converter configured to convert an analog signal as an input signal into a digital code composed of N bits (where N is a natural number), and includes: a reference signal input unit configured to provide a preset reference signal; and N bit processing units configured to correspond one-to-one with the N bits constituting the digital code and to receive the input signal and the reference signal to generate and output a code corresponding to a respective bit. Each of the bit processing units includes: a signal generation module including a first semiconductor device having a first threshold voltage set according to a corresponding bit position in the digital code and configured to receive the input signal; a comparison module including a second semiconductor device having a second threshold voltage and configured to receive the reference signal; a latch module configured to regenerate a potential of an internal node according to operation results of the first and second semiconductor devices based on the input signal, the first threshold voltage, the reference signal and the second threshold voltage; and a signal conversion module having an input node connected to an output node of the latch module and configured to convert an output voltage of the latch module into a binary signal and output the binary signal.

In the data converter according to the first aspect having the above features, each bit processing unit is preferably configured such that an output state of the latch module is determined according to a relative magnitude between a difference between the input signal and the first threshold voltage and a difference between the reference signal and the second threshold voltage, and accordingly an output signal of the signal conversion module is determined as one of logic values ‘1’ and ‘0’.

In the data converter according to the first aspect having the above features, each bit processing unit preferably further includes a charging module configured to initialize an output node of the latch module to a pre-charged state before a latch operation of the latch module.

In the data converter according to the first aspect having the above features, the first semiconductor device of the signal generation module of each bit processing unit is preferably configured as a semiconductor device having nonvolatile memory characteristics capable of varying a threshold voltage or conductance, or comprises one selected from the group consisting of a flash memory device, a resistive random-access memory device, a phase-change memory device, a ferroelectric memory device, a magnetoresistive memory device, and a field-effect transistor.

In the data converter according to the first aspect having the above features, the second semiconductor device of the comparison module of each bit processing unit is preferably configured as one selected from the group consisting of a field-effect transistor capable of generating a constant current, a resistive device, or as a device identical to the first semiconductor device.

In the data converter according to the first aspect having the above features, the latch module of each bit processing unit is preferably configured as two cross-coupled inverters, or as two NMOS transistors whose gates and drains are connected to each other, or as two PMOS transistors whose gates and drains are connected to each other.

In the data converter according to the first aspect having the above features, the signal conversion module of the bit processing unit is preferably configured as one selected from the group consisting of an inverter circuit, a buffer circuit, and a sense amplifier having a preset switching voltage.

In the data converter according to the first aspect having the above features, the first threshold voltages of the first semiconductor devices included in the N bit processing units are preferably linearly mapped at regular intervals according to positions of the corresponding bits.

In the data converter according to the first aspect having the above features, the first threshold voltages of the first semiconductor devices included in the N bit processing units are preferably nonlinearly mapped according to positions of the corresponding bits by using a nonlinear activation function.

In the data converter according to the first aspect having the above features, the N binary signals respectively output from the N bit processing units preferably constitute a thermometer code.

In the data converter according to the first aspect having the above features, the data converter preferably further comprises a thermometer-to-binary encoder configured to convert the thermometer code into a binary code, wherein the thermometer-to-binary encoder is connected to the N bit processing units, receives the thermometer code from the N bit processing units, and converts the thermometer code into the binary code to output the binary code.

In order to achieve the above technical object, a data converter according to a second aspect of the present invention is an analog-to-digital converter ADC configured to convert one or more analog signals as

input signals into a digital code composed of N bits (where N is a natural number), and includes N bit processing units configured to correspond one-to-one with the N bits constituting the digital code and to receive one or more input signals to generate and output codes corresponding to respective bits.

Each of the bit processing units includes: a signal generation module including one or more steep switching devices having threshold voltages set according to positions of corresponding bits in the digital code, wherein one or more input signals are respectively applied to control electrodes of the steep switching devices; a signal conversion module having an input node connected to an output node of the signal generation module, the voltage of the input node being changed according to an operation result of the signal generation module, and configured to convert the changed voltage of the input node into a binary signal and output the binary signal; and a precharge module connected to a power supply voltage and configured to precharge the input node of the signal conversion module according to a precharging signal.

In the data converter according to the second aspect having the above features, the steep switching device included in the signal generation module of each bit processing unit is preferably configured as one selected from the group consisting of a flash gated thyristor and a thyristor having a memory function.

In the data converter according to the second aspect having the above features, the signal conversion module is preferably configured as one selected from the group consisting of an inverter circuit, a buffer circuit, and a sense amplifier having a preset switching voltage.

In the data converter according to the second aspect having the above features, each of the bit processing units is preferably configured such that the input node of the signal conversion module is precharged by applying a precharging signal to the precharge module, and when the input signal is applied to the steep switching device, a potential of the output node of the steep switching device changes based on a relationship between the input signal and the threshold voltage, and an output code of the signal conversion module is determined according to the change in the potential of the output node of the steep switching device.

In the data converter according to the second aspect having the above features, a plurality of steep switching devices included in the signal generation module of each bit processing unit are connected in parallel, and the plurality of steep switching devices included in a single bit processing unit receive a plurality of input signals simultaneously, and the signal conversion module of the bit processing unit is configured to output a bit value corresponding to an input signal having the greatest influence on the change in the potential of the input node among the plurality of input signals, and the analog-to-digital converter preferably outputs a digital code corresponding to a result of a max pooling operation on the plurality of input signals.

In the data converter according to the second aspect having the above features, the threshold voltages of the steep switching devices included in the N bit processing units may be linearly mapped at regular intervals according to positions of the corresponding bits.

In the data converter according to the second aspect having the above features, the threshold voltages of the steep switching devices included in the N bit processing units may be nonlinearly mapped according to positions of the corresponding bits by using a nonlinear activation function.

In the data converter according to the second aspect having the above features, the N binary signals respectively output from the signal conversion modules of the N bit processing units preferably constitute a thermometer code.

In the data converter according to the second aspect having the above features, the data converter preferably further comprises a thermometer-to-binary encoder configured to convert the thermometer code into a binary code, wherein the thermometer-to-binary encoder is connected to the N bit processing units, receives the thermometer code from the N bit processing units, and converts the thermometer code into the binary code to output the binary code.

The data converter according to the present invention performs analog-to-digital conversion by using a latch circuit based on memory devices having different threshold voltages or steep switching devices, thereby simplifying the circuit configuration compared to conventional structures requiring a large number of comparators or complex analog circuits. Accordingly, the overall circuit area can be effectively reduced.

In addition, the data converter according to the present invention operates in a dynamic manner and has a structure in which charging and discharging occur only when necessary. Furthermore, by applying a latch-based decision mechanism utilizing steep switching characteristics, static current consumption can be minimized, thereby significantly reducing power consumption compared to conventional static-type analog-to-digital converters.

In addition, the data converter according to the present invention can rapidly amplify and determine a minute voltage difference of an input signal by utilizing a latch-based regeneration operation or threshold characteristics of steep switching devices. Accordingly, high-speed analog-to-digital conversion is possible, making the converter suitable for applications requiring high-speed signal processing.

In addition, the data converter according to the present invention can implement thermometer code generation, max pooling, and nonlinear activation characteristics at an analog signal stage through threshold voltage mapping or a structure of steep switching devices connected in parallel. Accordingly, the computational burden in a digital domain can be reduced and the computational efficiency of an overall system can be improved.

In addition, the data converter according to the present invention simultaneously provides advantages of reduced circuit area, reduced power consumption, and integrated computation in an analog domain, and thus can be effectively applied to neuromorphic networks, artificial intelligence accelerators, sensor interfaces, and in-memory computing systems requiring low-power operation.

### BRIEF DESCRIPTION OF THE DRAWINGS

FIG. 1 is a structural diagram illustrating a Flash ADC scheme according to the related art.

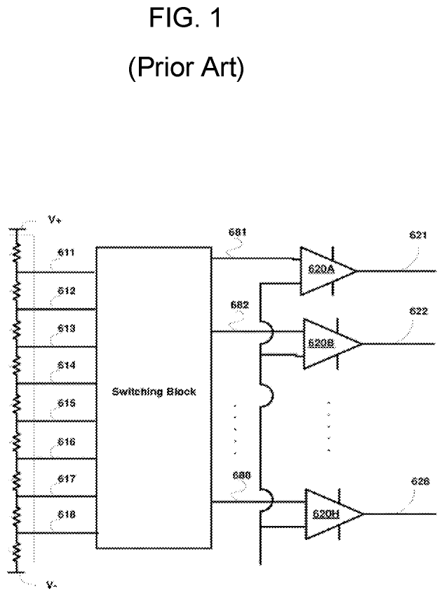

FIG. 2 is a structural diagram illustrating a SAR ADC scheme according to the related art.

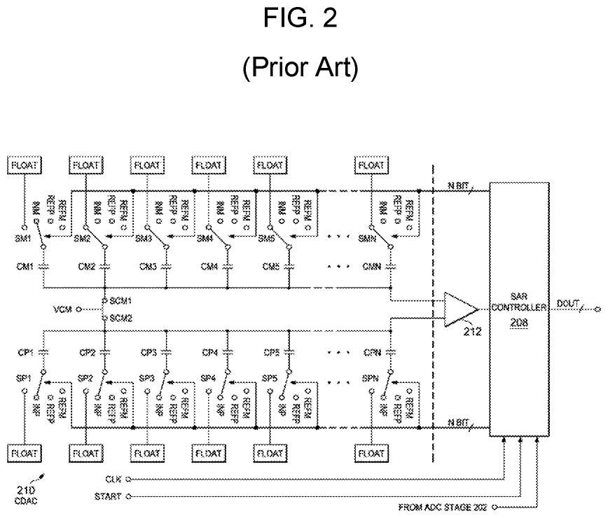

FIG. 3 is a configuration diagram illustrating an overall structure of a data converter according to a first embodiment of the present invention.

FIG. 4 is a circuit diagram illustrating a structure of an N-th bit processing unit 30-N in the data converter according to the first embodiment of the present invention.

FIG. 5 is a configuration diagram illustrating an overall structure of a data converter according to a second embodiment of the present invention.

FIG. 6 is a flowchart illustrating an operation of a bit processing unit in the data converter according to the second embodiment of the present invention.

FIGS. 7A and 7B are graphs illustrating an ADC operation when threshold voltages of steep switching devices are linearly mapped in the data converter according to the second embodiment of the present invention.

FIGS. 8A and 8B are graphs illustrating an ADC operation when threshold voltages of steep switching devices are nonlinearly mapped in the data converter according to the second embodiment of the present invention.

FIG. 9 is a configuration diagram illustrating an overall structure of a data converter according to a third embodiment of the present invention.

FIG. 10 is a diagram illustrating a thermometer code generated by performing max pooling on four input signals by seven bit processing units in the data converter according to the third embodiment of the present invention.

### DETAILED DESCRIPTION

The data converter according to the present invention is characterized in that unit cells composed of latch modules based on memory devices having different threshold voltages or steep switching devices having different threshold voltages are sequentially arranged to convert an analog signal into a digital code. The data converter according to the present invention converts an analog signal, which is an input signal, into a digital code composed of N bits (where N is a natural number) having binary values and outputs the digital code. Here, the digital code may be configured as a thermometer code composed of N bits (where N is a natural number). Hereinafter, structures and operations of data converters according to preferred embodiments of the present invention will be described in detail with reference to the accompanying drawings.

### First Embodiment

Hereinafter, the structure and operation of a data converter according to a first embodiment of the present invention will be described in detail with reference to the accompanying drawings. The data converter according to the first embodiment of the present invention is a dynamic analog-to-digital converter characterized by using a latch circuit module including semiconductor devices having different threshold voltages or conductances. Here, the digital code is configured as a thermometer code composed of N bits (where N is a natural number).

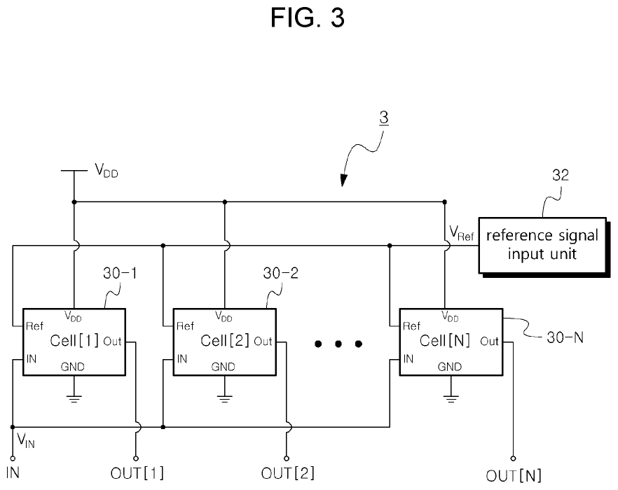

FIG. 3 is a configuration diagram illustrating an overall structure of a dynamic analog-to-digital converter according to the first embodiment of the present invention. Referring to FIG. 3, the dynamic analog-to-digital converter 3 according to the first embodiment of the present invention includes a reference signal input unit 32 and N bit processing units Cell[1: N] 30-1, 30-2, . . . , 30-N. The reference signal input unit 32 is configured to provide a preset reference signal V_{Ref} to the bit processing units. The N bit processing units Cell[1: N] are configured to correspond one-to-one with N bits constituting a digital code. The N bit processing units 30-1, 30-2, . . . , 30-N receive an input signal V_{IN} and the reference signal V_{Ref}, generate a code corresponding to a respective bit, and output the generated code. The dynamic analog-to-digital converter having the above configuration may generate and provide a digital code composed of a thermometer code based on N binary signals respectively output from the N bit processing units.

In the dynamic analog-to-digital converter according to the first embodiment of the present invention, each of the bit processing units Cell[1: N] is connected to a power supply voltage V_{DD} and a ground potential GND for circuit operation and is configured to commonly receive the input signal V_{IN} to be converted and the reference signal V_{Ref}. Each of the bit processing units Cell[1: N] includes semiconductor devices having mutually different threshold voltages Vₜₕ[1:N] and outputs a comparison result based on relative relationships among the threshold voltage, the input signal, and the reference signal. In particular, the dynamic analog-to-digital converter according to the present embodiment may be configured such that the threshold voltages of the semiconductor devices included in the bit processing units are sequentially mapped according to bit positions. As a result, the dynamic analog-to-digital converter according to the present embodiment generates a thermometer code, and the generated thermometer code may be used for digital conversion.

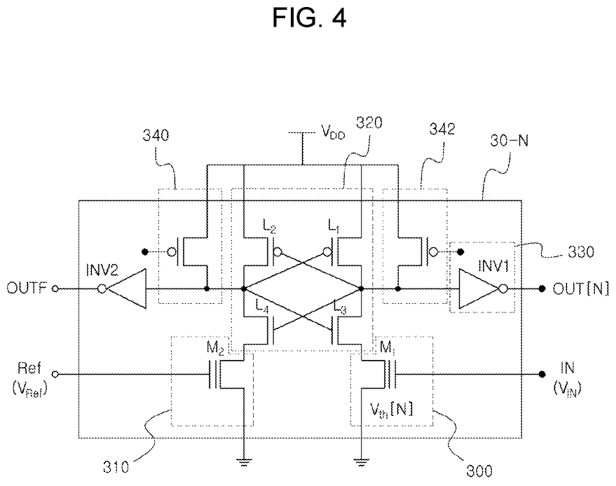

FIG. 4 is a circuit diagram illustrating a structure of an N-th bit processing unit Cell[N] 30-N in the dynamic analog-to-digital converter according to the first embodiment of the present invention. Hereinafter, the structure and operation of the bit processing unit will be described in detail with reference to FIG. 4. Although the circuit of FIG. 4 is implemented based on NMOS devices, it may also be implemented based on PMOS devices or implemented as a hybrid structure combining NMOS and PMOS devices. The dynamic analog-to-digital converter according to the first embodiment of the present invention uses a latch-based amplification mechanism, enabling rapid determination of an input signal, and is therefore advantageous for applications requiring high-speed analog-to-digital conversion.

Referring to FIG. 4, the N-th bit processing unit 30-N includes a signal generation module 300, a comparison module 310, a latch module 320, and a signal conversion module 330. Meanwhile, the bit processing unit 30 may further include precharge modules 340 and 342. In addition, the bit processing unit 30 may further include a threshold voltage adjustment module (not shown). Further, the bit processing unit 30 may further include a leakage blocking module (not shown).

The signal generation module 300 includes a first semiconductor device M1 having a threshold voltage Vₜₕ[N] determined according to the corresponding bit position N within the digital code. The input signal V_{IN} may be applied to a gate electrode of the first semiconductor device M1. In the dynamic analog-to-digital converter according to the present invention, the first semiconductor devices M1 of the signal generation modules 300 are configured such that their threshold voltages sequentially increase at regular intervals according to corresponding bit positions, and accordingly the analog input signal may be converted into a thermometer code.

In the data converter according to the present embodiment, the threshold voltages of the first semiconductor devices included in the N bit processing units may be linearly mapped at regular intervals according to positions of the corresponding bits, or may be nonlinearly mapped according to positions of the corresponding bits using a nonlinear activation function.

The first semiconductor device M1 may be configured as a semiconductor device having nonvolatile memory characteristics capable of varying a threshold voltage or conductance, or may be configured as one selected from the group consisting of a flash memory device, a resistive random-access memory device, a phase-change memory device, a ferroelectric memory device, a magnetoresistive memory device, and a field-effect transistor. In addition, the first semiconductor device M1 may be configured as a two-terminal device such as RRAM, PRAM, or an Ferroelectric Tunnel Junction device. Various methods for varying the threshold voltage or conductance of the first semiconductor device will be described later.

The comparison module 310 includes a second semiconductor device M2. The reference signal V_{Ref} is configured to be applied to a gate electrode of the second semiconductor device. The second semiconductor device M2 may be configured as one selected from the group consisting of a FET capable of generating a constant current and a resistive device.

The latch module 320 is a latch circuit configured to detect a state of an internal node corresponding to the input voltage according to operations of the first semiconductor device and the second semiconductor device, and to rapidly determine a potential of the internal node through a regeneration operation of potentials of the internal nodes. The latch module 320 may be configured as two cross-coupled inverters, or as two NMOS transistors whose gates and drains are connected to each other, or as two PMOS transistors whose gates and drains are connected to each other. In addition, the latch module 320 is not limited to these structures and may be implemented in various modified structures capable of performing a latch operation.

The signal conversion module 330 is configured to detect a voltage change generated by the latch module and convert the detected voltage change into a binary signal, and to output a code OUT[N] corresponding to a respective bit of the digital code. The signal conversion module 330 may be configured as one selected from the group consisting of an inverter circuit, a buffer circuit, and a sense amplifier. Accordingly, the signal conversion module 330 operates to determine an input voltage based on a preset switching voltage and generate a binary code.

The precharge modules 340 and 342 are composed of charging devices and connected to nodes of the latch module to precharge each node of the latch module to an initial state before a latch operation. The charging device may be one selected from the group consisting of a PMOS transistor, an NMOS transistor, a resistor, and a transmission gate.

Meanwhile, as described above, the first semiconductor device M1 of the signal generation module 300 is configured as a device capable of setting a threshold voltage or conductance to an arbitrary value. Accordingly, the first semiconductor device M1 of the signal generation module 300 may be implemented as: (1) a semiconductor device having nonvolatile memory characteristics capable of varying a threshold voltage or conductance, or (2) a semiconductor device in which the threshold voltage or conductance can be fixedly set during a design stage by adjusting parameters such as a coupling ratio. Therefore, depending on the type of device, the threshold voltage or conductance of the first semiconductor device M1 may be fixedly set during a design stage or may be variably adjusted during an operation stage by using nonvolatile memory characteristics. Hereinafter, methods for adjusting the threshold voltage or conductance for each device that may constitute the first semiconductor device M1 will be briefly described.

As described above, devices having nonvolatile memory characteristics that can be used as the first semiconductor device M1 of the signal generation module 300 include a flash memory device, a resistive random-access memory device, a phase-change memory device, a ferroelectric memory device, and a magnetoresistive memory device. Meanwhile, the dynamic analog-to-digital converter according to the present invention may further include a threshold voltage adjustment module to variously vary the threshold voltage or conductance of the first semiconductor device M1 having nonvolatile memory characteristics.

A flash memory device can adjust a threshold voltage or conductance by applying a voltage pulse to inject electrons or holes into a gate insulating layer. The electrons or holes injected into the gate insulating layer affect a channel. By utilizing this characteristic, in the case of an n-channel flash memory device, the threshold voltage of the device may be adjusted by injecting electrons to increase the threshold voltage or injecting holes to decrease the threshold voltage.

A resistive random-access memory device has a metal-insulator-metal structure, and a voltage pulse may be applied to induce a resistance change in an intermediate insulating layer to thereby vary conductance. In this case, the voltage pulse may be applied in a direction that increases conductance or in a direction that decreases conductance.

A ferroelectric memory device can change a threshold voltage or conductance by applying a voltage pulse to a ferroelectric insulating layer to form an electric field in the insulating layer. In the case of a field-effect transistor using the ferroelectric insulating layer as a gate insulating layer, an electric field may be formed in the ferroelectric insulating layer in a direction that increases conductance or may be adjusted in a direction that decreases conductance. In a ferroelectric tunnel junction device, conductance may be controlled by adjusting a tunneling probability of carriers through the direction and magnitude of an electric field in the ferroelectric insulating layer.

A magnetoresistive memory device includes a fixed layer, an insulating layer, and a free layer, and the fixed layer and the free layer have magnetic properties. A magnetization direction of the fixed layer is fixed, while a magnetization direction of the free layer can be changed. When a current is applied to the magnetoresistive memory device in a direction from the fixed layer to the free layer, the magnetization direction of the free layer becomes the same as that of the fixed layer, thereby increasing conductance. Meanwhile, when a current is applied to the magnetoresistive memory device in a direction opposite to the direction from the fixed layer to the free layer, the magnetization direction of the free layer becomes different from that of the fixed layer, thereby decreasing conductance. In this manner, conductance of the magnetoresistive memory device can be controlled using current.

When the first semiconductor device M1 of the signal generation module 300 is formed of a semiconductor device having a gate electrode or a control gate electrode, the threshold voltage of each device may be adjusted during a device and surrounding wiring design (physical layout) stage. As one example of such a method, when designing a device to include elements serving as a floating gate and a control gate by adjusting a physical layout of the device, the threshold voltage or conductance may be set by adjusting a coupling ratio between the gates. In addition, in the case of a device that does not include a floating gate or a charge storage layer, the threshold voltage or conductance may be set by adjusting coupling between the gate and surrounding metal wiring.

When the first semiconductor device M1 of the signal generation module 300 is designed to include elements serving as a floating gate and a control gate by adjusting a physical layout during a design stage, a coupling ratio by which a voltage of the control gate is transferred to the floating gate varies depending on a spacing or an area ratio between the two gates. Through this, even a semiconductor device without a memory function can have its threshold voltage or conductance set to a desired value in various ways.

In the case of a semiconductor device without a floating gate, the threshold voltage may be adjusted by controlling a coupling ratio between the gate electrode and surrounding electrodes. In this case, the gate electrode functions as a floating gate, and surrounding electrodes are designed to function as control gates. Here, the threshold voltage or conductance may be changed by adjusting the coupling ratio between the floating gate and the control gate.

When the first semiconductor device M1 of the signal generation module 300 is implemented as a device having nonvolatile memory characteristics, an additional threshold voltage adjustment module may be further included. By using the threshold voltage adjustment module, the threshold voltage or conductance may be varied according to a corresponding bit position and a resolution of each bit processing unit constituting the analog-to-digital converter.

The threshold voltage adjustment module may control an operation of the analog-to-digital converter by increasing or decreasing a threshold voltage or conductance of the first semiconductor device M1 of the signal generation module 300. The threshold voltage adjustment module may be configured as a pulse generator and may operate by applying pulses to the first semiconductor device to change a memory state thereof. In order to program or erase the threshold voltage of the first semiconductor device M1, a program/erase voltage may be applied to a gate terminal, and a voltage of ‘0’ may be applied to a source or a body or both. Meanwhile, when a program or erase operation is not desired, an inhibition voltage may be applied to a source, a body, a gate, or a plurality of these nodes, or these nodes may be floated.

Meanwhile, each of the bit processing units according to the present invention may further include a leakage blocking module. The leakage blocking module may be electrically connected to each of the signal generation module and the comparison module. The leakage blocking module may be configured as a semiconductor device having a polarity complementary to that of the precharge module. For example, when the precharge module is configured as a PMOS transistor, the leakage blocking module may be configured as an NMOS transistor. In addition, by applying the same control signal to a gate electrode of the leakage blocking module and a gate electrode of the precharge module, the leakage blocking module may effectively block leakage current that may occur while a node is precharged by the precharge module.

The dynamic analog-to-digital converter 3 according to the first embodiment having the above-described configuration operates based on a principle of rapidly amplifying a minute difference between an input signal and a reference voltage by using a sharp feedback effect of the latch module, and thereby rapidly discharging a potential of a specific node. Specifically, when a difference between the input signal applied to the first semiconductor device M1 and the first threshold voltage (V_{IN}−V_{th,M1[N]}) is greater than a difference between the reference signal applied to the second semiconductor device M2 and the second threshold voltage (V_{Ref}−V_{th,M2[N]}), an input node of the signal conversion module is rapidly discharged, and thus an output signal OUT[N] is determined as ‘1’ through an inverter included in the signal conversion module. On the other hand, when the difference between the input signal and the first threshold voltage is not greater than the difference between the reference signal and the second threshold voltage, the input node of the signal conversion module maintains a precharged state, and thus the output signal OUT[N] is determined as ‘1’ through the inverter included in the signal conversion module. As described above, the converter according to the first embodiment enables rapid signal discrimination through a high-speed regeneration operation using a latch structure, and therefore is suitable for analog-to-digital conversion applications requiring high-speed operation.

Meanwhile, the dynamic analog-to-digital converter according to the present embodiment may further include a thermometer-to-binary encoder configured to convert a thermometer code into a binary code. The thermometer-to-binary encoder may be connected to output terminals of the N bit processing units, receive the thermometer code from the N bit processing units, and convert the thermometer code into a binary code to output the converted binary code.

The dynamic analog-to-digital converter according to the first embodiment of the present invention having the above-described configuration may perform an analog-to-digital conversion operation using a single-module structure, and therefore may be applied in the field of in-memory computing. In addition, since the dynamic analog-to-digital converter according to the first embodiment operates in a dynamic manner, power consumption may be reduced compared with a static in-memory ADC. Accordingly, the dynamic analog-to-digital converter according to the first embodiment of the present invention may be effectively used in sensor systems and artificial intelligence application fields requiring low-power operation.

### Second Embodiment

Hereinafter, a structure and an operation of a data converter according to a second embodiment of the present invention will be described in detail with reference to the accompanying drawings. The data converter according to the second embodiment of the present invention is a dynamic analog-to-digital converter configured using steep switching devices having different threshold voltages. Here, a digital code is configured as a thermometer code composed of N bits (where N is a natural number).

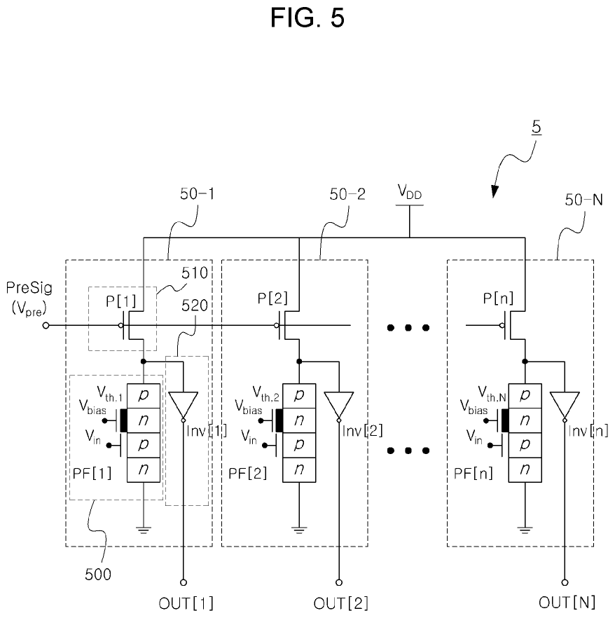

FIG. 5 is a block diagram illustrating an overall configuration of a data converter according to the second embodiment of the present invention. Referring to FIG. 5, the data converter according to the second embodiment of the present invention constitutes a dynamic analog-to-digital converter 5. The dynamic analog-to-digital converter 5 includes N bit processing units 50-1, 50-2, . . . , 50-N. The dynamic analog-to-digital converter according to the present embodiment having the above-described configuration may generate a digital code composed of a thermometer code based on N binary signals respectively output from the N bit processing units.

The N bit processing units 50-1, 50-2, . . . , 50-N are configured to correspond one-to-one with N bits constituting the digital code. The N bit processing units 50-1, 50-2, . . . , 50-N commonly receive a precharging signal Vₚᵣₑ and an input signal V_{IN}, and are configured to output binary signals OUT[1], OUT[2], . . . , OUT[N] corresponding to the respective bits. Here, the input signal V_{IN} is an analog signal to be converted. Each of the bit processing units includes a signal generation module 500, a precharge module 510, and a signal conversion module 520. Meanwhile, each of the bit processing units may further include a threshold voltage adjustment module (not shown).

The signal generation module 500 includes a steep switching device PF having a threshold voltage Vₜₕ set according to a corresponding bit position 1 to N within the digital code. In the present specification, a “steep switching device” refers to a device in which an output state rapidly switches in response to a small change in an input signal. The input signal Vₜₕ is applied to a control gate electrode of the steep switching device.

The steep switching device included in the signal generation module may be configured as a semiconductor device capable of generating a positive feedback or latch phenomenon. Examples of such semiconductor devices include a flash-gated thyristor employing charge-storage memory and a thyristor having a memory function based on a ferroelectric material. In this case, the devices may use both n-channel and p-channel types and may include three-terminal or four-terminal devices. In addition, the steep switching device of the signal generation module may be configured as a two-terminal switching device such as RRAM, PRAM, or a Ferroelectric Tunnel Junction device. However, the steeper the switching characteristics of the steep switching device used in the signal generation module, the more ideally a max pooling operation can be implemented.

The threshold voltages of the steep switching devices included in the N bit processing units may be linearly mapped at regular intervals according to positions of the corresponding bits, or may be nonlinearly mapped according to positions of the corresponding bits using a nonlinear activation function.

The threshold voltage adjustment module may be configured to vary threshold voltages or conductances of the plurality of steep switching devices included in the signal generation module according to a bit position corresponding to each bit processing unit and a resolution. Since a structure and operation of the threshold voltage adjustment module according to the present embodiment are the same as those of the first embodiment, redundant descriptions are omitted. Meanwhile, methods for adjusting threshold voltages or conductances of the steep switching devices according to the present embodiment are the same as those described in the first embodiment, and thus redundant descriptions are omitted.

The precharge module 510 is a module for precharging an input node Node 1 of the signal conversion module, and may be configured as a switching device connected between a driving power source and the input node Node 1 of the signal conversion module. The switching device constituting the precharge module 510 may be composed of a single MOSFET device, a plurality of MOSFET devices connected in series, or a transmission gate device, or may be composed of a nonvolatile memory device. During an initial operation of the dynamic analog-to-digital converter according to the present embodiment, the input node of the signal conversion module may be precharged to a driving voltage V_{DD} by applying a pulse-type precharging signal Vₚᵣₑ to the switching device of the precharge module.

The signal conversion module 520 is configured to convert a voltage of the input node into a binary signal and output a binary signal OUT corresponding to a bit in the digital code. The signal conversion module may be configured as one selected from the group consisting of an inverter circuit, a buffer circuit, and a sense amplifier. Accordingly, the signal conversion module operates to determine a voltage input to the signal conversion module based on a preset switching voltage and generate a binary signal.

The input node of the signal conversion module 520 is connected to an output terminal of the precharge module 510 and an anode terminal of the steep switching device PF included in the signal generation module 500. Accordingly, the input node of the signal conversion module may be precharged by the precharge module and may be rapidly discharged by a switching operation of the steep switching device. Through the charging and discharging operations of the input node of the signal conversion module, the signal conversion module is configured to generate and output a binary signal corresponding to the input signal.

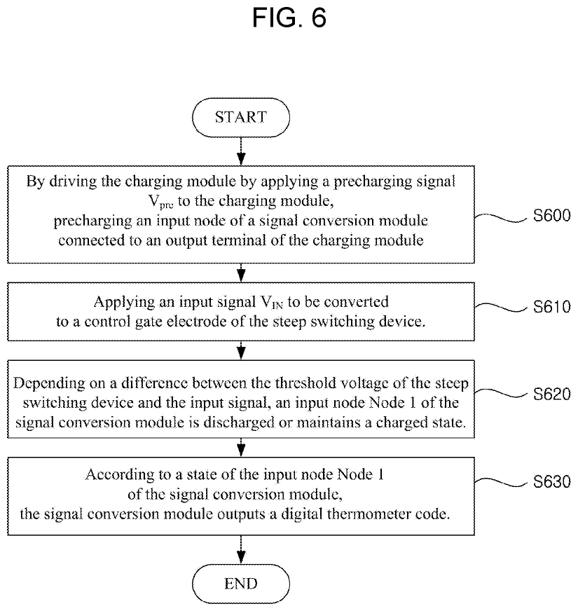

Hereinafter, an operation of a bit processing unit of the dynamic analog-to-digital converter according to the second embodiment of the present invention having the above-described configuration will be described. FIG. 6 is a flowchart illustrating the operation of the bit processing unit in the dynamic analog-to-digital converter according to the second embodiment of the present invention.

Referring to FIG. 6, first, a precharging signal Vₚᵣₑ is applied to a gate electrode of a switching device included in the precharge module to drive the switching device, thereby precharging an input node Node 1 of the signal conversion module connected to an output terminal of the precharge module (step 600).

Next, an input signal V_{IN} is applied to a control gate terminal of the steep switching device (step 610). Here, the input signal V_{IN} is an analog signal to be converted.

Thereafter, based on a relationship between a threshold voltage of the steep switching device and the input signal, the input node Node 1 of the signal conversion module is either discharged or maintains a precharged state (step 620). Specifically, when the input signal V_{IN} is greater than the threshold voltage of the steep switching device (V_{IN}>Vₜₕ), the steep switching device is turned on and discharges the input node Node 1 of the signal conversion module. On the other hand, when the input signal V_{IN} is not greater than the threshold voltage of the steep switching device (V_{IN}<Vₜₕ), the steep switching device remains turned off, and accordingly the input node Node 1 of the signal conversion module maintains the precharged state.

Next, the signal conversion module outputs a digital thermometer code according to a potential state of the input node Node 1 (step 630). That is, when the input node Node 1 of the signal conversion module is discharged, an output of an inverter included in the signal conversion module is determined as ‘1’. On the other hand, when the input node Node 1 of the signal conversion module maintains the precharged state, the output of the inverter of the signal conversion module is determined as ‘0’. The output of the inverter of the signal conversion module forms one bit of the digital thermometer code.

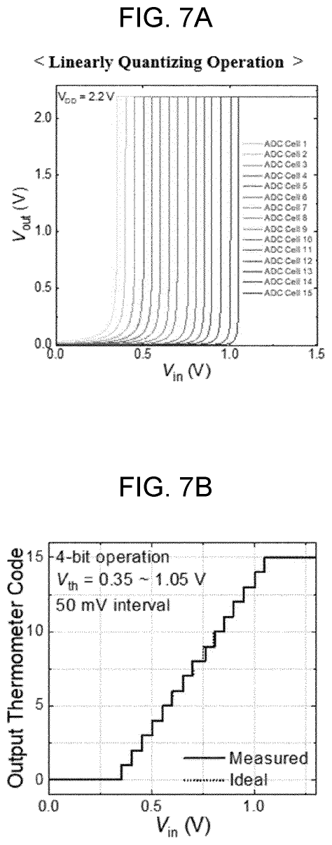

FIGS. 7A and 7B are graphs illustrating analog-to-digital conversion operations in the dynamic analog-to-digital converter according to the second embodiment of the present invention when threshold voltages of steep switching devices are linearly mapped. FIG. 7A is a graph illustrating a state in which threshold voltages of the steep switching devices are linearly mapped at regular intervals according to corresponding bits. FIG. 7B is a graph illustrating a thermometer code output as an input voltage is converted according to the linearly mapped threshold voltages. From FIGS. 7A and 7B, it can be confirmed that when threshold voltages of the steep switching devices are linearly mapped according to corresponding bits, the analog-to-digital conversion operation is also performed linearly.

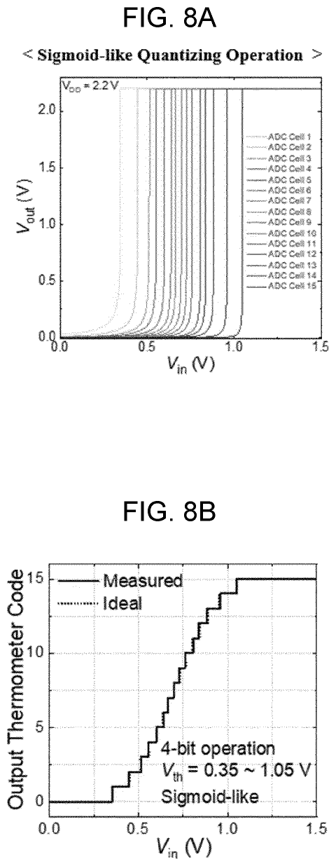

FIGS. 8A and 8B are graphs illustrating analog-to-digital conversion operations in the dynamic analog-to-digital converter according to the second embodiment of the present invention when threshold voltages of steep switching devices are nonlinearly mapped. FIG. 8A is a graph illustrating a state in which threshold voltages of the steep switching devices are nonlinearly mapped according to corresponding bits. FIG. 8B is a graph illustrating a thermometer code output as an input voltage is converted based on the nonlinearly mapped threshold voltages. From FIGS. 8A and 8B, it can be confirmed that when threshold voltages of the steep switching devices are nonlinearly mapped according to corresponding bits, nonlinear activation characteristics such as a sigmoid function or a tanh function can be performed simultaneously with the analog-to-digital conversion operation.

From FIGS. 7 and 8, it can be confirmed that the dynamic analog-to-digital converter according to the second embodiment of the present invention can control a distribution and an increment characteristic of a thermometer code by adjusting intervals of the threshold voltages of the steep switching devices.

Meanwhile, the dynamic analog-to-digital converter according to the present embodiment may further include a thermometer-to-binary encoder configured to convert a thermometer code into a binary code. The thermometer-to-binary encoder may be connected to output terminals of the N bit processing units, receive the thermometer code from the N bit processing units, and convert the thermometer code into a binary code to output the converted binary code.

### THIRD EMBODIMENT

Hereinafter, a structure and operation of a data converter according to a third embodiment of the present invention will be described in detail with reference to the accompanying drawings. The data converter according to the third embodiment of the present invention is a dynamic analog-to-digital converter configured to enable max pooling by using steep switching devices having different threshold voltages. Here, the digital code is configured as a thermometer code composed of N bits (where N is a natural number).

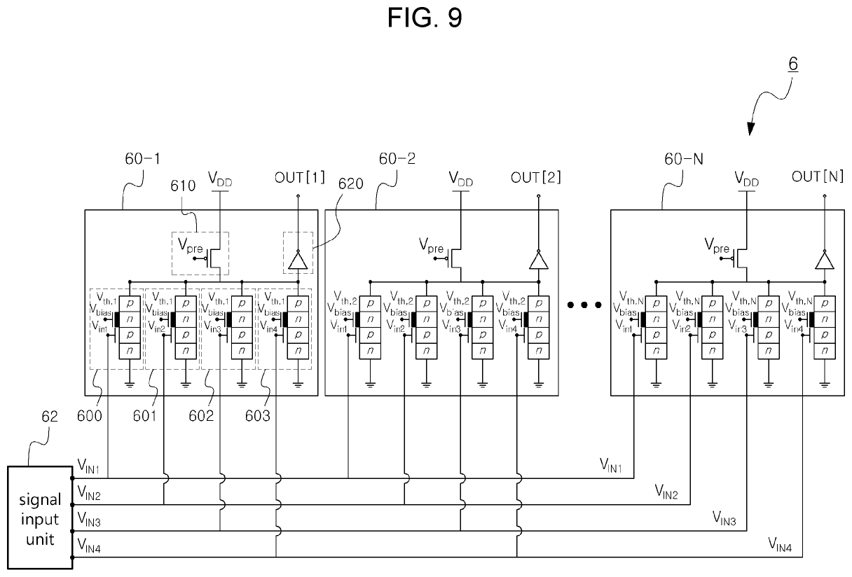

FIG. 9 is a block diagram illustrating an overall configuration of a data converter according to the third embodiment of the present invention. Referring to FIG. 9, the data converter according to the third embodiment of the present invention constitutes a dynamic analog-to-digital converter 6. The dynamic analog-to-digital converter 6 includes N bit processing units 60-1, 60-2, . . . , 60-N and a signal input unit 62.

The signal input unit 62 is configured to commonly provide a plurality of input signals V_{IN1}, V_{IN2}, V_{IN3}, and V_{IN4}, which are to be converted, to the N bit processing units 60-1, 60-2, . . . , 60-N.

The N bit processing units 60-1, 60-2, . . . , 60-N are configured to correspond one-to-one with N bits constituting the digital code. The N bit processing units 60-1, 60-2, . . . , 60-N commonly receive a precharging signal Vₚᵣₑ and a plurality of input signals V_{IN1}, V_{IN2}, V_{IN3}, and V_{IN4}, and are configured to perform a max pooling operation on the plurality of input signals and output codes corresponding to the respective bits. Here, the plurality of input signals V_{IN1}, V_{IN2}, V_{IN3,}, and V_{IN4} are a plurality of analog signals to be subjected to a max pooling operation.

Each of the bit processing units 60 includes a plurality of signal generation modules 600, 601, 602, and 603, a precharge module 610, and a signal conversion module 620. Meanwhile, each of the bit processing units may further include a threshold voltage adjustment module (not shown). In the dynamic analog-to-digital converter according to the present embodiment having the above-described configuration, the plurality of input signals are subjected to a max pooling operation on a bit-by-bit basis in the bit processing units, and a digital code composed of a thermometer code obtained through the max pooling operation may be generated based on N codes output from the bit processing units.

The signal generation modules 600, 601, 602, and 603 include a plurality of steep switching devices PF having threshold voltages Vₜₕ determined according to positions of corresponding bits in the digital code, and the steep switching devices included in the signal generation modules 600, 601, 602, and 603 are connected in parallel with each other. Since the structure and operation of the steep switching devices in the present embodiment are the same as those of the second embodiment, redundant descriptions are omitted. The threshold voltages of the steep switching devices included in the N bit processing units may be linearly mapped at regular intervals according to positions of corresponding bits, or may be nonlinearly mapped according to positions of corresponding bits using a nonlinear activation function.

The precharge module 610 is a module for precharging an input node Node 1 of the signal conversion module, and may be configured as a switching device connected between a driving voltage and the input node Node 1 of the signal conversion module. During an initial operation of the ADC according to the present embodiment, the input node of the signal conversion module may be precharged to a driving voltage V_{DD} by applying a pulse-type precharging signal Vₚᵣₑ to the switching device of the precharge module. Since the structure and operation of the precharge module 610 in the present embodiment are the same as those of the second embodiment, redundant descriptions are omitted.

The signal conversion module 620 is configured to convert a voltage of the input node into a binary signal and output a binary signal OUT corresponding to a bit in the digital code. Accordingly, the signal conversion module operates to determine a voltage input to the signal conversion module based on a preset switching voltage and generate a binary signal. Since the structure and operation of the signal conversion module 620 in the present embodiment are the same as those of the second embodiment, redundant descriptions are omitted.

An input node of signal conversion module 620 is connected to an output terminal of precharge module 610 and to an anode terminal of steep switching devices PF included in signal generation modules 600, 601, 602, and 603. Accordingly, the input node of signal conversion module 620 may be precharged by precharge module 610 and may be rapidly discharged by switching operations of the steep switching devices. Through charging and discharging operations of the input node of signal conversion module 620, signal conversion module 620 is configured to generate and output a binary signal corresponding to an input signal.

The threshold voltage adjustment module is configured to vary threshold voltages or conductances of the plurality of steep switching devices included in the signal generation module according to a bit position corresponding to each bit processing unit and a resolution. Since a structure and operation of the threshold voltage adjustment module according to the present embodiment are the same as those of the second embodiment, redundant descriptions are omitted. Meanwhile, methods for adjusting threshold voltages or conductances of the steep switching devices according to the present embodiment are the same as those described in the second embodiment, and thus redundant descriptions are omitted.

Hereinafter, an operation of the bit processing unit of the dynamic analog-to-digital converter according to the third embodiment of the present invention having the above-described configuration will be described.

First, a precharging signal Vₚᵣₑ is applied to a gate electrode of a switching device included in precharge module 610 to drive the switching device, thereby precharging input node Node 1 of signal conversion module 620 connected to an output terminal of precharge module 610.

Next, input signals V_{IN1}, V_{IN2}, V_{IN3}, and V_{IN4} are respectively applied to control gate terminals of the plurality of steep switching devices 600, 601, 602, and 603 included in the signal generation module. Here, input signals V_{IN1}, V_{IN2}, V_{IN3}, and V_{IN4} are a plurality of analog signals to be subjected to a max pooling operation.

Thereafter, based on a relationship between threshold voltages of the steep switching devices and the plurality of input signals, input node Node 1 of signal conversion module 620 is either discharged or maintained in a precharged state. Specifically, when one or more of the plurality of input signals V_{IN1}, V_{IN2}, V_{IN3}, and V_{IN4} is greater than the threshold voltage of the steep switching device, one or more of the steep switching devices are turned on and input node Node 1 of signal conversion module 620 is discharged. On the other hand, when all of the plurality of input signals V_{IN1}, V_{IN2}, V_{IN3}, and V_{IN4} are not greater than the threshold voltage of the steep switching device, all of the steep switching devices remain turned off, and accordingly input node Node 1 of signal conversion module 620 maintains the precharged state.

Next, a digital thermometer code is output according to a potential state of input node Node 1 of signal conversion module 620. That is, when input node Node 1 of signal conversion module 620 is discharged, an output of an inverter included in signal conversion module 620 is determined as ‘1’. On the other hand, when input node Node 1 of signal conversion module 620 maintains the precharged state, the output of the inverter of signal conversion module 620 is determined as ‘0’. The output of the inverter of signal conversion module 620 forms one bit of the digital thermometer code. Accordingly, when a plurality of input signals are applied, the N-th bit processing unit of the converter according to the present embodiment outputs a max mooling-operated binary signal OUT[N] as follows:
OUT[N]=‘1’, if max(V_{IN1}, V_{IN2}, V_{IN1}, V_{IN4})>Vₜₕ
OUT[N]=‘0’, if max(V_{IN1}, V_{IN2}, V_{IN1}, V_{IN4})<Vₜₕ

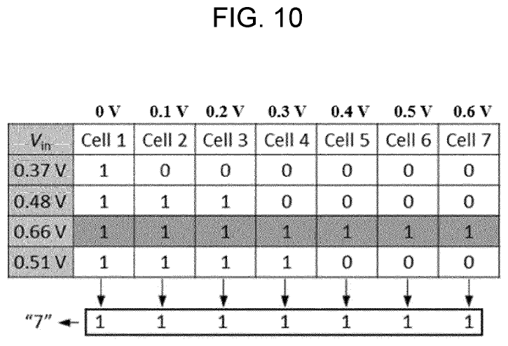

FIG. 10 is a diagram illustrating a thermometer code generated by max pooling four input signals by seven bit processing units in the data converter according to the third embodiment of the present invention. Referring to FIG. 10, the plurality of input signals V_{IN1}, V_{IN2}, V_{IN3}, and V_{IN4} are respectively 0.37 V, 0.48 V, 0.66 V, and 0.51 V. Threshold voltages of the seven bit processing units are respectively set to 0 V, 0.1 V, 0.2 V, 0.3 V, 0.4 V, 0.5 V, and 0.6 V. In this case, the dynamic ADC according to the present embodiment performs a max pooling operation on the plurality of input signals and outputs a thermometer code “1111111”.

The data converter according to the present embodiment can perform a max pooling operation on a plurality of input signals during an analog-to-digital conversion process by configuring the signal generation module as a plurality of steep switching devices connected in parallel. Specifically, when any one of the signals input to the plurality of steep switching devices connected in parallel exceeds a corresponding threshold voltage, input node Node 1 of signal conversion module 620 is discharged, and as a result a digital thermometer code corresponding to the largest input signal is output.

Meanwhile, the data converter according to the present embodiment may further include a thermometer-to-binary encoder configured to convert a thermometer code into a binary code. The thermometer-to-binary encoder may be connected to output terminals of the N bit processing units, receive the thermometer code from the N bit processing units, and convert the thermometer code into a binary code to output the converted binary code.

As described above, the data converter according to the present embodiment is configured such that the largest input signal dominates circuit operation, thereby enabling a max pooling operation to be effectively implemented in an analog signal stage before conversion into a digital code. Accordingly, since a separate pooling operation does not need to be performed in a digital domain, computational overhead may be reduced and overall computational efficiency may be improved. Therefore, the dynamic analog-to-digital converter according to the present embodiment may be usefully applied in machine learning and neuromorphic computing environments where pooling operations are frequently required.

Although the present invention has been described above with reference to preferred embodiments, these embodiments are merely illustrative and are not intended to limit the present invention. Those skilled in the art will appreciate that various modifications and applications not illustrated above may be made without departing from the essential characteristics of the present invention. Differences associated with such modifications and applications should be interpreted as falling within the scope of the present invention defined by the appended claims.

What is claimed is:

1. A data converter configured to convert an analog signal, which is an input signal, into a digital code composed of N bits, where N is a natural number, the data converter comprising:
a reference signal input unit configured to provide a preset reference signal; and
N bit processing units configured to respectively correspond one-to-one to the N bits constituting the digital code and receive the input signal and the reference signal to generate and output a code of a corresponding bit,
wherein each of the bit processing units comprises:
a signal generation module including a first semiconductor device having a first threshold voltage set according to a corresponding bit position within the digital code, the input signal being applied to the signal generation module; and
a comparison module including a second semiconductor device having a second threshold voltage, the reference signal being applied to the comparison module;
a latch module configured to regenerate a potential of an internal node according to operation results of the first semiconductor device and the second semiconductor device based on the input signal, the first threshold voltage, the reference signal and the second threshold voltage; and
a signal conversion module having an input node connected to an output node of the latch module and configured to convert an output voltage of the latch module into a binary signal and output the binary signal.

2. The data converter of claim 1, wherein each of the bit processing units is configured such that an output state of the latch module is determined according to a relative magnitude between a difference between the input signal and the first threshold voltage and a difference between the reference signal and the second threshold voltage, and wherein an output signal of the signal conversion module is determined as one of a logic value ‘1’ and a logic value ‘0’.

3. The data converter of claim 1, wherein each of the bit processing units further comprises:
a charging module configured to initialize an output node of the latch module to a precharged state before a latch operation of the latch module.

4. The data converter of claim 1, wherein the first semiconductor device of the signal generation module of each bit processing unit is configured as a semiconductor device having nonvolatile memory characteristics such that a threshold voltage or conductance is variable, or is configured as one selected from the group consisting of a flash memory device, a resistive random-access memory device, a phase-change memory device, a ferroelectric memory device, a magnetoresistive memory device, and a field-effect transistor.

5. The data converter of claim 1, wherein the second semiconductor device of the comparison module of each bit processing unit is configured as one selected from the group consisting of a field-effect transistor and a resistive device capable of generating a constant current, or is configured as the same device as the first semiconductor device.

6. The data converter of claim 1, wherein the latch module of each of the bit processing units is configured as two cross-coupled inverters, or is configured as two NMOS transistors whose gates and drains are connected to each other, or is configured as two PMOS transistors whose gates and drains are connected to each other.

7. The data converter of claim 1, wherein the signal conversion module of the bit processing units is configured as one selected from the group consisting of an inverter circuit having a preset switching voltage, a buffer circuit, and a sense amplifier.

8. The data converter of claim 1, wherein the first threshold voltages of the first semiconductor devices included in the N bit processing units are linearly mapped at regular intervals according to positions of corresponding bits.

9. The data converter of claim 1, wherein the first threshold voltages of the first semiconductor devices included in the N bit processing units are nonlinearly mapped according to positions of corresponding bits using a nonlinear activation function.

10. The data converter of claim 1, wherein N binary signals respectively output from the N bit processing units constitute a thermometer code.

11. The data converter of claim 1, further comprising a thermometer-to-binary encoder configured to convert a thermometer code into a binary code,
wherein the thermometer-to-binary encoder is connected to the N bit processing units, receives the thermometer code from the N bit processing units, and converts the thermometer code into the binary code to output the binary code.

12. A data converter configured to convert one or more analog signals, which are input signals, into a digital code composed of N bits, where N is a natural number, the data converter comprising:
N bit processing units configured to respectively correspond one-to-one to the N bits constituting the digital code and configured to receive the one or more input signals to generate and output codes of corresponding bits,
wherein each of the bit processing units comprises:
a signal generation module including one or more steep switching devices having threshold voltages set according to positions of corresponding bits within the digital code, control electrodes of the steep switching devices being configured to receive the one or more input signals respectively;
a signal conversion module having an input node connected to an output node of the signal generation module and configured such that a voltage of the input node changes according to an operation result of the signal generation module, and the changed voltage of the input node is converted into a binary signal and output the binary signal; and
a precharge module connected to a power supply voltage and configured to precharge the input node of the signal conversion module according to a precharging signal.

13. The data converter of claim 12, wherein the steep switching device included in the signal generation module of each bit processing unit is configured as one selected from the group consisting of a flash gated thyristor and a thyristor having a memory function.

14. The data converter of claim 12, wherein the signal conversion module is configured as one selected from the group consisting of an inverter circuit having a preset switching voltage, a buffer circuit, and a sense amplifier.

15. The data converter of claim 12, wherein each of the bit processing units is configured such that, after a precharging signal is applied to the precharge module to precharge the input node of the signal conversion module, when the input signal is applied to the steep switching device, a potential of an output node of the steep switching device changes based on a relationship between the input signal and the threshold voltage, and an output code of the signal conversion module is determined according to the change in the potential of the output node of the steep switching device.

16. The data converter of claim 12, wherein a plurality of steep switching devices included in the signal generation module of each bit processing unit are connected in parallel,
wherein the plurality of steep switching devices included in each bit processing unit simultaneously receive respective input signals,
wherein the signal conversion module of each bit processing unit is configured to output a bit value corresponding to an input signal causing a greatest change in potential of an input node among the plurality of input signals, and
wherein the analog-to-digital converter outputs a digital code corresponding to a result of a max pooling operation performed on the plurality of input signals.

17. The data converter of claim 12, wherein threshold voltages of the steep switching devices included in the N bit processing units are linearly mapped at regular intervals according to positions of corresponding bits.

18. The data converter of claim 12, wherein threshold voltages of the steep switching devices included in the N bit processing units are nonlinearly mapped according to positions of corresponding bits using a nonlinear activation function.

19. The data converter of claim 12, wherein N binary signals respectively output from the signal conversion modules of the N bit processing units constitute a thermometer code.

20. The data converter of claim 12, further comprising a thermometer-to-binary encoder configured to convert a thermometer code into a binary code,
wherein the thermometer-to-binary encoder is connected to the N bit processing units, receives the thermometer code from the N bit processing units, and converts the thermometer code into the binary code to output the binary code.
